(19) United States
(12) Patent Application Publication
(10) Pub. No.: US 2025/0374683 A1
(43) Pub. Date: Dec. 4, 2025

(54) ELECTROSTATIC DISCHARGE PROTECTION IN A MULTI-DIE RADIO FREQUENCY MODULE

(71) Applicant: Skyworks Solutions, Inc., Irvine, CA (US)

(72) Inventor: Lui Ray Lam, Lexington, MA (US)

(21) Appl. No.: 19/224,582

(22) Filed: May 30, 2025

Related U.S. Application Data
(60) Provisional application No. 63/654,284, filed on May 31, 2024.
(60) Provisional application No. 63/675,161, filed on Jul. 24, 2024.

(51) Int. Cl. H10D 89/60; H01Q 1/50; H04B 1/40

(52) U.S. Cl. CPC H10D 89/811; H01Q 1/50; H04B 1/40

(57) ABSTRACT

A semiconductor module including a power supply pin a compound semiconductor die. The compound semiconductor die includes a first amplifying transistor and a first matching component of an impedance matching network. The first matching component is coupled to an output of the first amplifying transistor and is configured to pass low frequency. The module includes a silicon-based die including electrostatic discharge circuitry coupled, via an inter-die connection between the compound semiconductor die and the silicon-based die, to an output of the first matching component. The silicon-based die further includes a radio frequency switching device and a second matching component of the impedance matching network configured to block low frequency. The second matching component is coupled between the output of the first matching component and the radio frequency switching device.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

Embodiments of this disclosure relate to electrostatic discharge (ESD) protection through radio frequency components in integrated circuits.

### Description of Related Technology

Continued advances in semiconductor technology have resulted in integrated circuits (ICs) with decreasing geometries. As the ICs become miniaturized, however, they can become more susceptible to damage from an electrostatic discharge (ESD) event, which can include rapid, high-current events resulting from high voltage created when electrostatic charges are rapidly transferred between bodies at different electrical potentials. If not properly contained, an ESD event can lead to either a reduction in IC performance, e.g., increased leakage current on one or more pins of the IC chip, or total circuit failure.

To provide ESD protection, some semiconductor manufacturers implement ESD circuitry to provide a conductive path between a power bus and ground when an ESD event occurs on the power bus.

### SUMMARY

In some aspects, the techniques described herein relate to a radio frequency module including: a power supply pin; a module substrate; a first die supported by the module substrate and coupled to the power supply pin, the first die including an amplifying transistor powered by a signal received on the power supply pin and configured to output an amplified radio frequency signal, the first die further including a first passive component coupled to an output of the amplifying transistor; and a second die supported by the module substrate, the second die including electrostatic discharge circuitry, a radio frequency device, and a second passive component, the first passive component forming part of a direct current (DC) path between the power supply pin and the electrostatic discharge circuitry, the second passive component in a path extending from the power supply pin, through the first passive component, to the radio frequency device, and the second passive component configured to block direct current (DC) signal from reaching the radio frequency device while passing to the radio frequency device the amplified radio frequency signal.

In some aspects, the techniques described herein relate to a radio frequency module wherein the first die is a compound semiconductor die.

In some aspects, the techniques described herein relate to a radio frequency module wherein the second die is a silicon-based die.

In some aspects, the techniques described herein relate to a radio frequency module wherein the second die is a complementary metal-oxide-semiconductor die or a silicon-on-insulator die.

In some aspects, the techniques described herein relate to a radio frequency module wherein the amplifying transistor is a heterojunction bipolar transistor or a Pseudomorphic High-Electron-Mobility-Transistor.

In some aspects, the techniques described herein relate to a radio frequency module wherein the first passive component is an inductor.

In some aspects, the techniques described herein relate to a radio frequency module wherein the second passive component is a capacitor.

In some aspects, the techniques described herein relate to a radio frequency module wherein the first passive component and the second passive component form part of an impedance matching network configured matches the amplifying transistor to the radio frequency device.

In some aspects, the techniques described herein relate to in The radio frequency module wherein the first die is supported by the module substrate in a position such that the first die is between the power supply pin and the second die.

In some aspects, the techniques described herein relate to a semiconductor module including: a power supply pin; a module substrate; a first die supported by the module substrate and coupled to the power supply pin, the first die including a first passive component; and a second die supported by the module substrate, the second die including electrostatic discharge circuitry, a radio frequency device, a second passive component, the first passive component forming part of a direct current (DC) path between the power supply pin and the electrostatic discharge circuitry, the second passive component in a path between the power supply pin and the radio frequency device and configured to block direct current (DC) from reaching the radio frequency device.

In some aspects, the techniques described herein relate to a semiconductor module wherein the first die is a compound semiconductor die.

In some aspects, the techniques described herein relate to a semiconductor module wherein the first die is a III-V semiconductor die.

In some aspects, the techniques described herein relate to a semiconductor module wherein the second die is a silicon-based die.

In some aspects, the techniques described herein relate to a semiconductor module wherein the second die is a complementary metal-oxide-semiconductor die or a silicon-on-insulator die.

In some aspects, the techniques described herein relate to a semiconductor module wherein the first die further includes a heterojunction bipolar transistor or a Pseudomorphic High-Electron-Mobility-Transistor powered by a supply signal provided by the power supply pin.

In some aspects, the techniques described herein relate to a semiconductor module wherein the first passive component is an inductor.

In some aspects, the techniques described herein relate to a semiconductor module wherein the second passive component is a capacitor.

In some aspects, the techniques described herein relate to a semiconductor module wherein the first die includes an amplifying transistor, and the first passive component and the second passive component form a radio frequency matching network that matches the amplifying transistor of the first die to the radio frequency device.

In some aspects, the techniques described herein relate to a semiconductor module wherein the first die is supported by the module substrate in a position such that the first die is positioned between the power supply pin and the second die.

In some aspects, the techniques described herein relate to a mobile device including: a transceiver; an antenna; and a semiconductor module between the transceiver and the antenna, the semiconductor module including a power supply pin; a module substrate, a first die supported by the module substrate and coupled to the power supply pin, the first die including a first passive component, and the semiconductor module further including a second die supported by the module substrate, the second die including electrostatic discharge circuitry, a radio frequency device, a second passive component, the first passive component forming part of a direct current (DC) path between the power supply pin and the electrostatic discharge circuitry, the second passive component in a path between the power supply pin and the radio frequency device and configured to block direct current (DC) from reaching the radio frequency device.

In some aspects, the techniques described herein relate to a mobile device wherein the first die is a compound semiconductor die.

In some aspects, the techniques described herein relate to a mobile device wherein the first die is a III-V semiconductor die.

In some aspects, the techniques described herein relate to a mobile device wherein the second die is a silicon-based die.

In some aspects, the techniques described herein relate to a mobile device wherein the second die is a complementary metal-oxide-semiconductor die or a silicon-on-insulator die.

In some aspects, the techniques described herein relate to a mobile device wherein the first passive component is an inductor.

In some aspects, the techniques described herein relate to a mobile device wherein the second passive component is a capacitor.

In some aspects, the techniques described herein relate to a mobile device wherein the first die is supported by the module substrate in a position such that the first die is between the power supply pin and the second die.

In some aspects, the techniques described herein relate to a semiconductor module including: a power supply pin; a module substrate; a compound semiconductor die supported by the module substrate, the compound semiconductor die including a first amplifying transistor and a first matching component of an impedance matching network, the first matching component coupled to an output of the first amplifying transistor and configured to pass low frequency; and a silicon-based die supported by the module substrate, the silicon-based die including electrostatic discharge circuitry coupled, via an inter-die connection between the compound semiconductor die and the silicon-based die, to an output of the first matching component, the silicon-based die further including a radio frequency switching device and a second matching component of the impedance matching network configured to block low frequency, the second matching component coupled between the output of the first matching component and the radio frequency switching device.

In some aspects, the techniques described herein relate to a semiconductor module wherein the compound semiconductor die is a III-V semiconductor die.

In some aspects, the techniques described herein relate to a semiconductor module wherein the silicon-based die is a complementary metal-oxide-semiconductor die or a silicon-on-insulator die.

In some aspects, the techniques described herein relate to a semiconductor module wherein the first amplifying transistor is a heterojunction bipolar transistor or a Pseudomorphic High-Electron-Mobility-Transistor.

In some aspects, the techniques described herein relate to a semiconductor module wherein the first matching component is an inductor.

In some aspects, the techniques described herein relate to a semiconductor module wherein the second matching component is a capacitor.

In some aspects, the techniques described herein relate to a semiconductor module wherein the impedance matching network matches the output of the first amplifying transistor to an input of the radio frequency switching device.

In some aspects, the techniques described herein relate to a semiconductor module wherein the compound semiconductor die is supported by the module substrate in a position such that the compound semiconductor die is between the power supply pin and the silicon-based die.

In some aspects, the techniques described herein relate to a mobile device including: a transceiver; an antenna; and a semiconductor module between the transceiver and the antenna, the semiconductor module including a compound semiconductor die supported by a module substrate and a silicon-based die supported by the module substrate, the compound semiconductor die including a first amplifying transistor and a first matching component of an impedance matching network, the first matching component coupled to an output of the first amplifying transistor and configured to pass low frequency, the silicon-based die including electrostatic discharge circuitry coupled, via an inter-die connection between the compound semiconductor die and the silicon-based die, to an output of the first matching component, the silicon-based die further including radio frequency switching device and a second matching component of the impedance matching network configured to block low frequency, the second matching component coupled between the output of the first matching component and the radio frequency switching device.

In some aspects, the techniques described herein relate to a mobile device wherein the compound semiconductor die is a III-V semiconductor die.

In some aspects, the techniques described herein relate to a mobile device wherein the silicon-based die is a complementary metal-oxide-semiconductor die or a silicon-on-insulator die.

In some aspects, the techniques described herein relate to a mobile device wherein the first amplifying transistor is a heterojunction bipolar transistor or a Pseudomorphic High-Electron-Mobility-Transistor.

In some aspects, the techniques described herein relate to a mobile device wherein the first matching component is an inductor.

In some aspects, the techniques described herein relate to a mobile device wherein the second matching component is a capacitor.

In some aspects, the techniques described herein relate to a mobile device wherein the impedance matching network matches the output of the first amplifying transistor to an input of the radio frequency switching device.

In some aspects, the techniques described herein relate to a mobile device wherein the compound semiconductor die is supported by the module substrate in a position such that the compound semiconductor die is between a power supply pin of the semiconductor module and the silicon-based die.

In some aspects, the techniques described herein relate to a semiconductor module including: a power supply pin; a module substrate; a compound semiconductor die supported by the module substrate, the compound semiconductor die including a first radio frequency component and a first matching component of an impedance matching network, the first matching component coupled to an output of the first radio frequency component and configured to pass low frequency; and a silicon-based die supported by the module substrate, the silicon-based die including electrostatic discharge circuitry coupled, via an inter-die connection between the compound semiconductor die and the silicon-based die, to an output of the first matching component, the silicon-based die further including a second radio frequency component and a second matching component of the impedance matching network configured to block low frequency, the second radio frequency component coupled between the output of the first matching component and the second radio frequency component.

In some aspects, the techniques described herein relate to a semiconductor module wherein the compound semiconductor die is a III-V semiconductor die.

In some aspects, the techniques described herein relate to a semiconductor module wherein the silicon-based die is a complementary metal-oxide-semiconductor die or a silicon-on-insulator die.

In some aspects, the techniques described herein relate to a semiconductor module wherein the first radio frequency component is a power amplifier.

In some aspects, the techniques described herein relate to a semiconductor module wherein the second radio frequency component is a radio frequency switching device.

In some aspects, the techniques described herein relate to a semiconductor module wherein the first matching component is an inductor.

In some aspects, the techniques described herein relate to a semiconductor module wherein the second matching component is a capacitor.

In some aspects, the techniques described herein relate to a semiconductor module including: a power supply pin; a module substrate; a first die supported by the module substrate, the first die including a first transistor and a first matching component of a radio frequency matching network; and a second die supported by the module substrate, the second die including electrostatic discharge circuitry and a second matching component of the radio frequency matching network, the radio frequency matching network configured to match an impedance associated with the first transistor, the first matching component providing a conductive path between the electrostatic discharge circuitry and the power supply pin.

In some aspects, the techniques described herein relate to a semiconductor module wherein the first die is a compound semiconductor die.

In some aspects, the techniques described herein relate to a semiconductor module wherein the first die is a III-V semiconductor die.

In some aspects, the techniques described herein relate to a semiconductor module wherein the second die is a silicon-based die.

In some aspects, the techniques described herein relate to a semiconductor module wherein the second die is a complementary metal-oxide-semiconductor die or a silicon-on-insulator die.

In some aspects, the techniques described herein relate to a semiconductor module wherein the first transistor is a heterojunction bipolar transistor or a Pseudomorphic High-Electron-Mobility-Transistor.

In some aspects, the techniques described herein relate to a semiconductor module wherein the first matching component is an inductor.

In some aspects, the techniques described herein relate to a semiconductor module wherein the second matching component is a capacitor.

In some aspects, the techniques described herein relate to a semiconductor module wherein the radio frequency matching network matches the first transistor to a load in the second die.

In some aspects, the techniques described herein relate to a semiconductor module wherein the first die is supported by the module substrate in a position such that the first die is between the power supply pin and the second die.

In some aspects, the techniques described herein relate to a radio frequency module including: a module substrate and a first die supported by the module substrate and a second die supported by the module substrate, the first die including a first transistor and a first matching component of a radio frequency matching network, the second die including electrostatic discharge circuitry and a second matching component of the radio frequency matching network, the radio frequency matching network configured to match an impedance associated with the first transistor, the first matching component providing a conductive path between the electrostatic discharge circuitry and a power supply pin.

In some aspects, the techniques described herein relate to a radio frequency module wherein the first die is a compound semiconductor die.

In some aspects, the techniques described herein relate to a radio frequency module wherein the second die is a silicon-based die.

In some aspects, the techniques described herein relate to a radio frequency module wherein the second die is a complementary metal-oxide-semiconductor die or a silicon-on-insulator die.

In some aspects, the techniques described herein relate to a radio frequency module wherein the first transistor is a heterojunction bipolar transistor or a Pseudomorphic High-Electron-Mobility-Transistor.

In some aspects, the techniques described herein relate to a radio frequency module wherein the first matching component is an inductor.

In some aspects, the techniques described herein relate to a radio frequency module wherein the second matching component is a capacitor.

In some aspects, the techniques described herein relate to a radio frequency module wherein the radio frequency matching network matches the first transistor to a load in the second die.

In some aspects, the techniques described herein relate to a radio frequency module wherein the first die is supported by the module substrate in a position such that the first die is between the power supply pin and the second die.

In some aspects, the techniques described herein relate to a mobile device including: a transceiver; an antenna; and a semiconductor module between the transceiver and the antenna, the semiconductor module including a first die supported by a module substrate and a second die supported by the module substrate, the first die including a first transistor and a first matching component of a radio frequency matching network, the second die including electrostatic discharge circuitry and a second matching component of the radio frequency matching network, the radio frequency matching network configured to match an impedance associated with the first transistor, the first matching component providing a conductive path between the electrostatic discharge circuitry and a power supply pin.

In some aspects, the techniques described herein relate to a mobile device wherein the first die is a compound semiconductor die.

In some aspects, the techniques described herein relate to a mobile device 20 or 21 wherein the first die is a III-V semiconductor die.

In some aspects, the techniques described herein relate to a mobile device wherein the second die is a silicon-based die.

In some aspects, the techniques described herein relate to a mobile device wherein the second die is a complementary metal-oxide-semiconductor die or a silicon-on-insulator die.

In some aspects, the techniques described herein relate to a mobile device wherein the first matching component is an inductor.

In some aspects, the techniques described herein relate to a mobile device wherein the second matching component is a capacitor.

In some aspects, the techniques described herein relate to a mobile device wherein the first die is supported by the module substrate in a position such that the first die is between the power supply pin and the second die.

### BRIEF DESCRIPTION OF THE DRAWINGS

Embodiments of this disclosure will now be described, by way of non-limiting example, with reference to the accompanying drawings.

FIG. 1 is a schematic diagram of one example of a communication network.

FIG. 2A is a schematic diagram of one example of a communication link using carrier aggregation.

FIG. 2B illustrates various examples of uplink carrier aggregation for the communication link of FIG. 2A.

FIG. 2C illustrates various examples of downlink carrier aggregation for the communication link of FIG. 2A.

FIG. 3A is a schematic diagram of one example of a downlink channel using multi-input and multi-output (MIMO) communications.

FIG. 3B is schematic diagram of one example of an uplink channel using MIMO communications.

FIG. 3C is schematic diagram of another example of an uplink channel using MIMO communications.

FIG. 4 is a schematic diagram of a packaged module in accordance with some embodiments of the present disclosure.

FIG. 5 is a schematic diagram of a packaged module in accordance with some embodiments of the present disclosure.

FIG. 6A is a schematic diagram of a packaged module in accordance with some embodiments of the present disclosure.

FIG. 6B is a schematic diagram of a packaged module in accordance with some embodiments of the present disclosure.

FIG. 7 is a schematic diagram of ESD circuitry in accordance with some embodiments of the present disclosure.

FIG. 8 is a schematic diagram of one embodiment of a mobile device.

FIG. 9A is a schematic diagram of one embodiment of a packaged module.

FIG. 9B is a schematic diagram of a cross-section of the packaged module of FIG. 9A taken along the lines 9B-9B.

### DETAILED DESCRIPTION OF CERTAIN EMBODIMENTS

Generally described, one or more aspects of the present disclosure disclose integrated circuits that utilize radio frequency (RF) components (e.g., a RF matching network) for front-end circuitry to form a conductive trace between a power supply pin of a packaged module and ESD circuitry for implementing ESD protection. This may avoid the need of using more expensive packaging technologies such as multi-chip modules (MCM) and molded interconnect substrate (MIS), or routing through the front-end circuitry to form the conductive trace between the power supply pin and the ESD circuitry. This in turn reduces cost of packing semiconductor dies or coupling issues between the front-end circuitry and the conductive trace for discharging an ESD charge on the power supply pin.

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

### Overview

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IoT), Vehicle-to-Everything (V2X), and High Power User Equipment (HPUE).

3GPP introduced Phase 1 of fifth generation (5G) technology in Release 15, and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

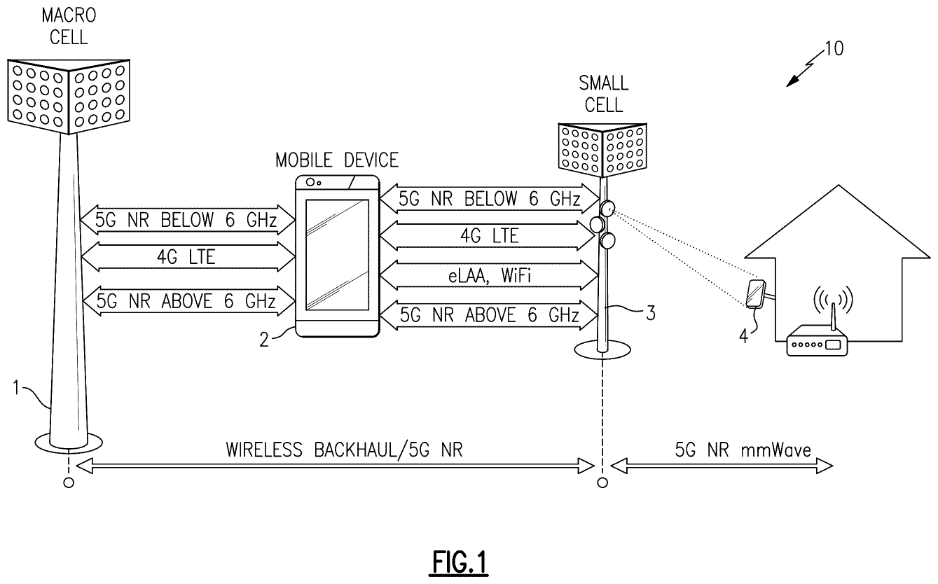

FIG. 1 is a schematic diagram of one example of a communication network 10. The communication network 10 includes a macro cell base station 1, a mobile device 2, a small cell base station 3, and a stationary wireless device 4.

The illustrated communication network 10 of FIG. 1 supports communications using a variety of technologies, including, for example, 4G LTE, 5G NR, and wireless local area network (WLAN), such as WiFi. Although various examples of supported communication technologies are shown, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

As shown in FIG. 1, the mobile device 2 communicates with the macro cell base station 1 over a communication link that uses a combination of 4G LTE and 5G NR technologies. The mobile device 2 also communications with the small cell base station 3. In the illustrated example, the mobile device 2 and small cell base station 3 communicate over a communication link that uses 5G NR, 4G LTE, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

In certain implementations, the mobile device 2 communicates with the macro cell base station 2 and the small cell base station 3 using 5G NR technology over one or more frequency bands that are less than 6 Gigahertz (GHz) and/or over one or more frequency bands that are greater than 6 GHz. For example, wireless communications can utilize Frequency Range 1 (FR1) in the range of about 410 MHz to about 7.125 GHZ, Frequency Range 2 (FR2) in the range of about 24.250 GHz to about 52.600 GHz, or a combination thereof. In one embodiment, the mobile device 2 supports a HPUE power class specification.

The illustrated small cell base station 3 also communicates with a stationary wireless device 4. The small cell base station 3 can be used, for example, to provide broadband service using 5G NR technology. In certain implementations, the small cell base station 3 communicates with the stationary wireless device 4 over one or more millimeter wave frequency bands in the frequency range of 30 GHz to 300 GHz and/or upper centimeter wave frequency bands in the frequency range of 24 GHz to 30 GHz.

In certain implementations, the small cell base station 3 communicates with the stationary wireless device 4 using beamforming. For example, beamforming can be used to focus signal strength to overcome path losses, such as high loss associated with communicating over millimeter wave frequencies.

The communication network 10 of FIG. 1 includes the macro cell base station 1 and the small cell base station 3. In certain implementations, the small cell base station 3 can operate with relatively lower power, shorter range, and/or with fewer concurrent users relative to the macro cell base station 1. The small cell base station 3 can also be referred to as a femtocell, a picocell, or a microcell.

Although the communication network 10 is illustrated as including two base stations, the communication network 10 can be implemented to include more or fewer base stations and/or base stations of other types. As shown in FIG. 1, base stations can communicate with one another using wireless communications to provide a wireless backhaul. Additionally or alternatively, base stations can communicate with one another using wired and/or optical links.

The communication network 10 of FIG. 1 is illustrated as including one mobile device and one stationary wireless device. The mobile device 2 and the stationary wireless device 4 illustrate two examples of user devices or user equipment (UE). Although the communication network 10 is illustrated as including two user devices, the communication network 10 can be used to communicate with more or fewer user devices and/or user devices of other types. For example, user devices can include mobile phones, tablets, laptops, IoT devices, wearable electronics, and/or a wide variety of other communications devices.

User devices of the communication network 10 can share available network resources (for instance, available frequency spectrum) in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user device a unique code, space-divisional multiple access (SDMA) in which beamforming is used to provide shared access by spatial division, and non-orthogonal multiple access (NOMA) in which the power domain is used for multiple access. For example, NOMA can be used to serve multiple user devices at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user device. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to eMBB, uRLLC, and/or mMTC.

A peak data rate of a communication link (for instance, between a base station and a user device) depends on a variety of factors. For example, peak data rate can be affected by channel bandwidth, modulation order, a number of component carriers, and/or a number of antennas used for communications.

For instance, in certain implementations, a data rate of a communication link can be about equal to M*B*log₂(1+S/N), where M is the number of communication channels, B is the channel bandwidth, and S/N is the signal-to-noise ratio (SNR).

Accordingly, data rate of a communication link can be increased by increasing the number of communication channels (for instance, transmitting and receiving using multiple antennas), using wider bandwidth (for instance, by aggregating carriers), and/or improving SNR (for instance, by increasing transmit power and/or improving receiver sensitivity).

5G NR communication systems can employ a wide variety of techniques for enhancing data rate and/or communication performance.

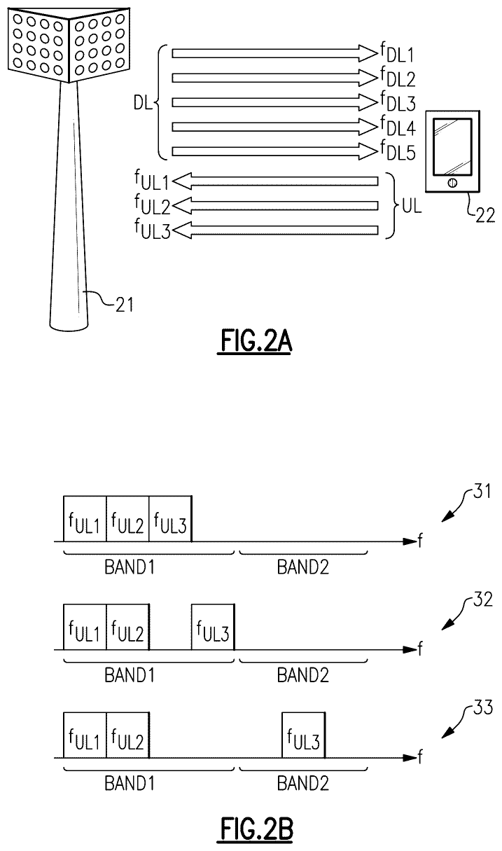

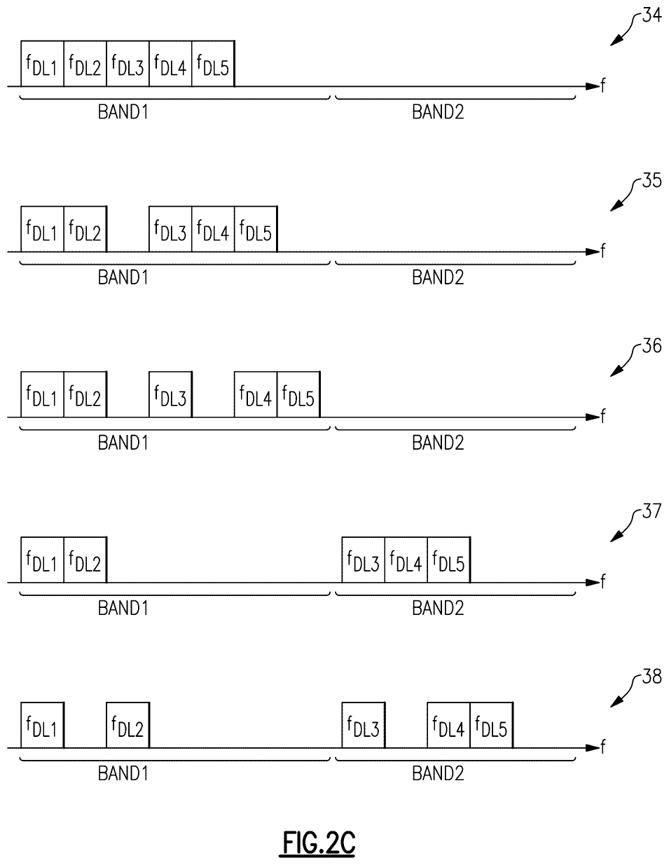

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations.

In the illustrated example, the communication link is provided between a base station 21 and a mobile device 22. As shown in FIG. 2A, the communications link includes a downlink channel used for RF communications from the base station 21 to the mobile device 22, and an uplink channel used for RF communications from the mobile device 22 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, the base station 21 and the mobile device 22 communicate via carrier aggregation, which can be used to selectively increase bandwidth of the communication link. Carrier aggregation includes contiguous aggregation, in which contiguous carriers within the same operating frequency band are aggregated. Carrier aggregation can also be non-contiguous, and can include carriers separated in frequency within a common band or in different bands.

In the example shown in FIG. 2A, the uplink channel includes three aggregated component carriers F_{UL1}, F_{UL2}, and F_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier f_{UL1}, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous, but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As a number of aggregated component carriers increases, a complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and secondary cells may have different coverage areas, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as WiFi. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid WiFi users and/or to coexist with WiFi users. Enhanced license assisted access (eLAA) refers to an evolution of LAA that aggregates licensed and unlicensed spectrum for both downlink and uplink.

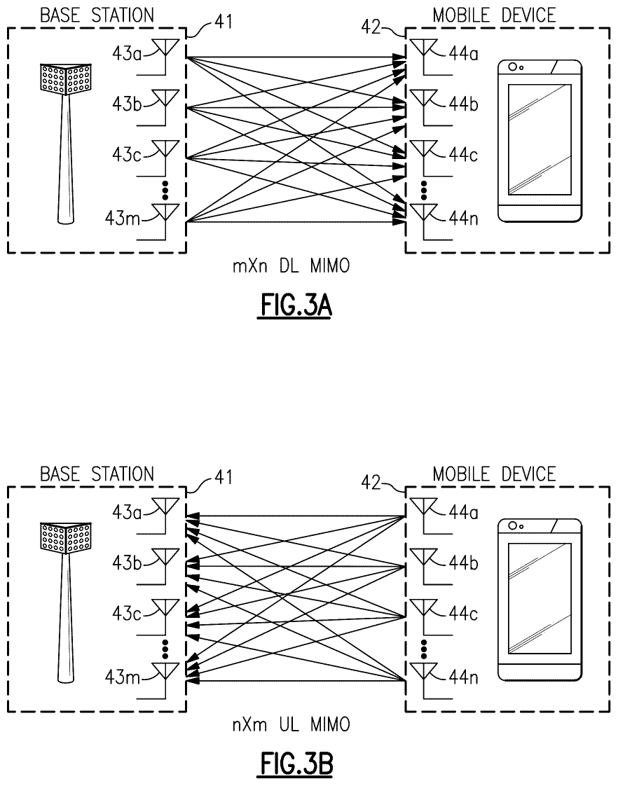

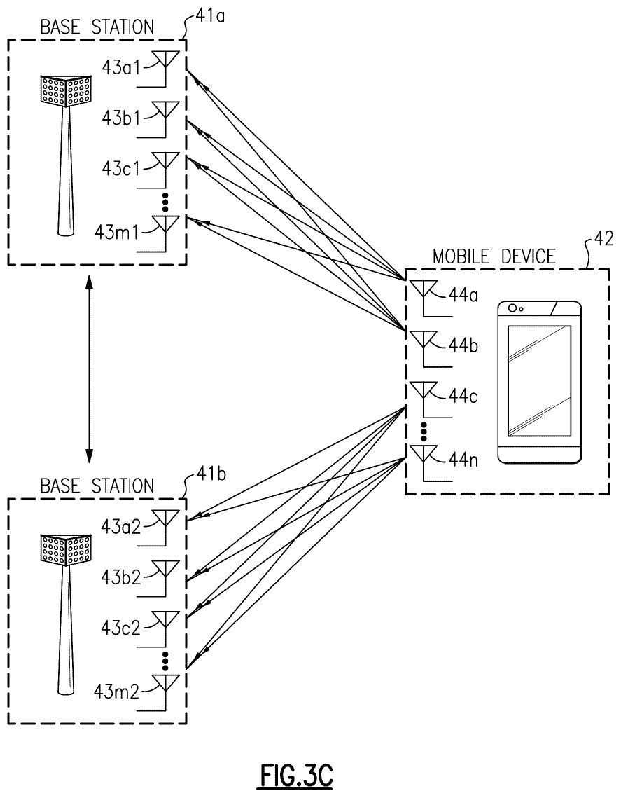

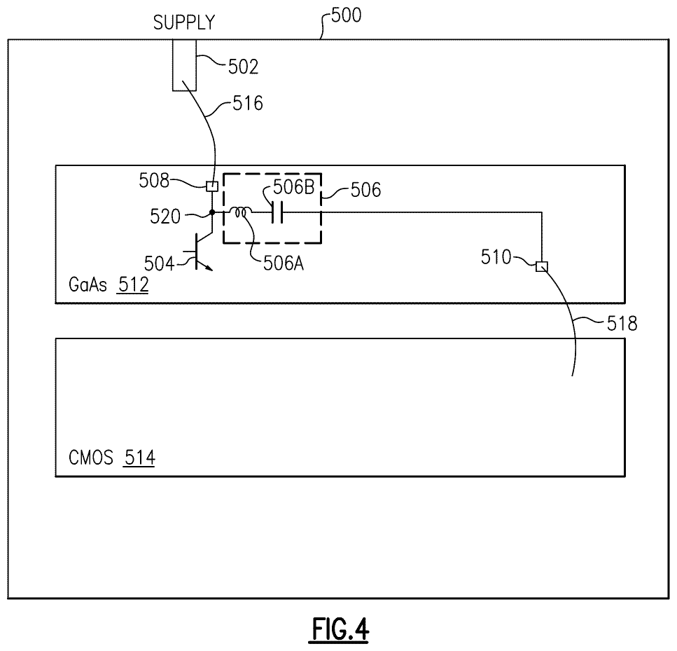

FIG. 3A is a schematic diagram of one example of a downlink channel using multi-input and multi-output (MIMO) communications. FIG. 3B is schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 3A, downlink MIMO communications are provided by transmitting using M antennas 43a, 43b, 43c, . . . 43m of the base station 41 and receiving using N antennas 44a, 44b, 44c, . . . 44n of the mobile device 42. Accordingly, FIG. 3A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 3B, uplink MIMO communications are provided by transmitting using N antennas 44a, 44b, 44c, . . . 44n of the mobile device 42 and receiving using M antennas 43a, 43b, 43c, . . . 43m of the base station 41. Accordingly, FIG. 3B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

FIG. 3C is schematic diagram of another example of an uplink channel using MIMO communications. In the example shown in FIG. 3C, uplink MIMO communications are provided by transmitting using N antennas 44a, 44b, 44c, . . . 44n of the mobile device 42. Additional a first portion of the uplink transmissions are received using M antennas 43a1, 43b1, 43c1, . . . 43m1 of a first base station 41a, while a second portion of the uplink transmissions are received using M antennas 43a2, 43b2, 43c2, . . . 43m2 of a second base station 41b. Additionally, the first base station 41a and the second base station 41b communication with one another over wired, optical, and/or wireless links.

The MIMO scenario of FIG. 3C illustrates an example in which multiple base stations cooperate to facilitate MIMO communications.

### Electrostatic Discharge (ESD) Protection in RF Communication Systems

RF communication systems discussed above generally include front-end circuitry which couples one or more antennas, such as a multi-die radio frequency module including transmit and receive paths that communicate RF signals to/from a baseband system. According to certain embodiments, RF communication systems employ silicon-based semiconductor devices such as those implemented in one or more complementary metal-oxide-semiconductor (CMOS) or silicon-on-insulator (SOI) dies to provide certain functionality and corresponding components (e.g., switching, control, electrostatic discharge protection), and compound semiconductor devices, such as those implemented in one or more III-V semiconductor dies (e.g., GaAs or GaN-based dies) to provide certain other functionality and corresponding components (e.g., amplification using one or more heterojunction bipolar transistors [HBTs] or Pseudomorphic High-Electron-Mobility-Transistors [pHEMTs] to provide radio frequency front-end functionalities. In these systems, components such as the transistor-based radio frequency amplifiers may be deployed on a compound semiconductor die like a III-V semiconductor (e.g., GaAs or GaN) die, e.g., because such technology can provide relatively good performance for amplifying radio frequency signals, and other componentry (e.g., switching, control, and ESD protection circuitry) system may be deployed on a CMOS or silicon-on-insulator (SOI) die, e.g., because such technology may provide more available devices and thus more design flexibility. The III-V semiconductor die and the CMOS die may be packaged into a packaged module.

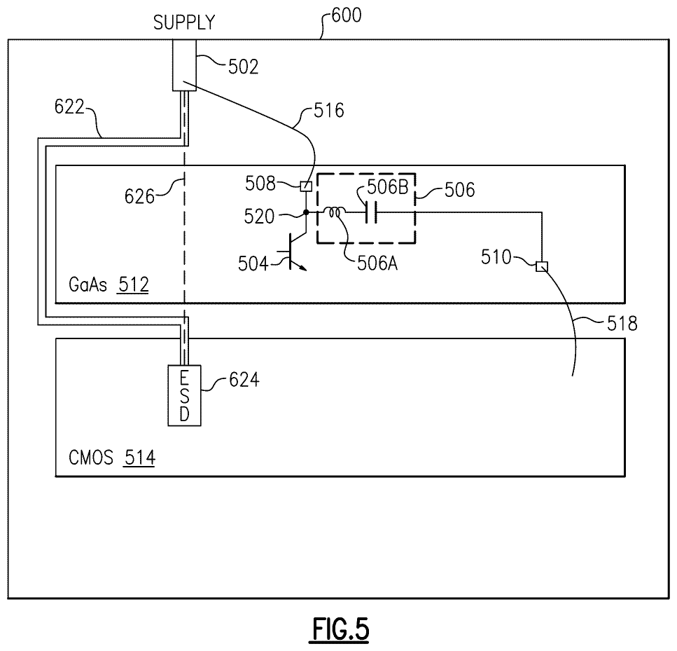

FIG. 4 is a schematic diagram of a packaged module 500 in accordance with some embodiments of the present disclosure. For example, the packaged module 500 can be a radio frequency front end module. As shown in FIG. 4, the packaged module 500 includes a GaAs die 512 mounted on a module substrate. While the illustrated embodiment includes a GaAs die, other implementations can include other types of compound semiconductor dies, including other III-V type semiconductor dies such as GaN dies. The packaged module 500 also includes a CMOS die 514 mounted on the module substrate. While the illustrated embodiment includes a bulk CMOS die 514, other implementations can include other types of silicon-based dies including SOI dies, for example. The module 500 also includes a power supply pin 502. The GaAs die 512 includes a HBT 504, a terminal 508, a terminal 510, and a matching network 506 that includes an inductor 506A and a capacitor 506B. The power supply pin 502 is connected to the terminal 508 through a bond wire 516.

Depending on the embodiment, the power supply pin 502 can be any appropriate lead, pad, ball-type contact, or the like for connecting to the module 600 via an external component (e.g., a phone board).

The terminal 508 is connected to a collector 520 of the HBT 504. The terminal 510 is connected to the CMOS die 514 through a bond wire 518. The HBT 504 and the matching network 506 may coordinate to provide certain front-end functionalities (e.g., impedance matching for amplifying RF signals) for the packaged module 500. For example, the matching network 506 may match output impedance of the HBT 504 to a load (not shown in FIG. 4). Thus, the supply pin 502 may connect a supply to the collector 520 of the HBT 504 to power the HBT 504. For example, the HBT 504 may be an amplifying transistor of a transistor power amplifier or low noise amplifier that amplifies a radio frequency signal received on the base of the HBT 504 and outputs an amplified radio frequency signal on the collector 520 of the HBT 504. Moreover, the HBT 504 drives a load (not shown) on the CMOS die 514, and provides the amplified radio frequency signal to the load, which can be a radio frequency switch or other component.

While certain exemplary circuitry is shown in the radio frequency front end module 500, it will be appreciated that additional componentry can be included, such as one or more additional transistors and/or passive components to form one or more transmit power amplifiers, receive low noise amplifiers, radio frequency switches, etc.

In some RF communication applications, as illustrated in FIG. 4, the power supply pin 502 is deployed around or closer to the GaAs die 512 and placed farther away from the CMOS die 514. In some other embodiments, to provide some level of ESD protection, ESD circuitry (not shown in FIG. 4) may be fabricated on the GaAs die 512 and connected to (e.g., through the terminal 508) the power supply pin 502 for discharging an ESD charge on the power supply pin 502. However, the ESD circuitry fabricated on the GaAs die 512 may provide inferior or less sophisticated ESD protection compared with other ESD circuitry fabricated on the CMOS die 514.

More specifically, due to process limitations, fewer types of devices (e.g., only HBTs available in some cases) and circuits (e.g., an inverter chain may not be available) can be manufactured on the GaAs die 512. As such, the ESD circuitry fabricated on the GaAs die 512 may not support more sophisticated ESD protection, such as detecting a voltage or a current spike during an ESD event and turning on a pull-down circuit to discharge the ESD charge in response to the detection. Additionally, transistors fabricated on the GaAs die 512 may be capable of tolerating smaller voltage spikes compared with their CMOS counterparts.

Thus, it may be desirable to fabricate ESD circuitry on the CMOS die 514 to provide ESD protection on the power supply pin 502. Yet, straightforward implementations of the EDS circuitry on the CMOS die 514 may lead to other technical issues as described below.

### (1) ESD Protection Through Trace Routing Around or Across a Die

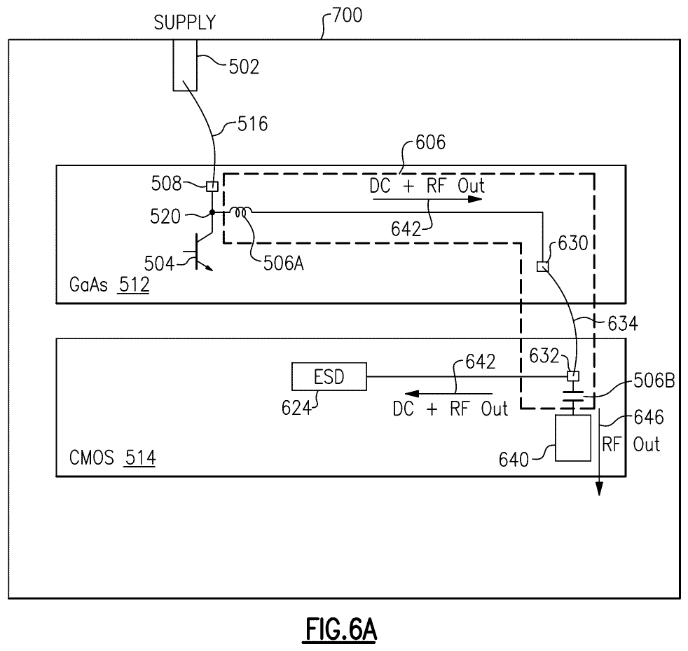

FIG. 5 is a schematic diagram of a packaged module 600 in accordance with some embodiments of the present disclosure. As shown in FIG. 5, the packaged module 600 includes the GaAs die 512, the CMOS die 514, and the power supply pin 502. The GaAs die 512 includes the HBT 504, the terminal 508, the terminal 510, and the matching network 506 that includes the inductor 506A and the capacitor 506B. The CMOS die 514 includes ESD circuitry 624. The power supply pin 502 is connected to the terminal 508 through a bond wire 516. The terminal 508 is connected to the collector 520 of the HBT 504. The terminal 510 is connected to the CMOS die 514 through a bond wire 518. The HBT 504 may form part of a transistor based amplifier such as a transmit power amplifier or low noise receive amplifier, whereas the matching network 506 may provide impedance matching for amplifying RF signals.

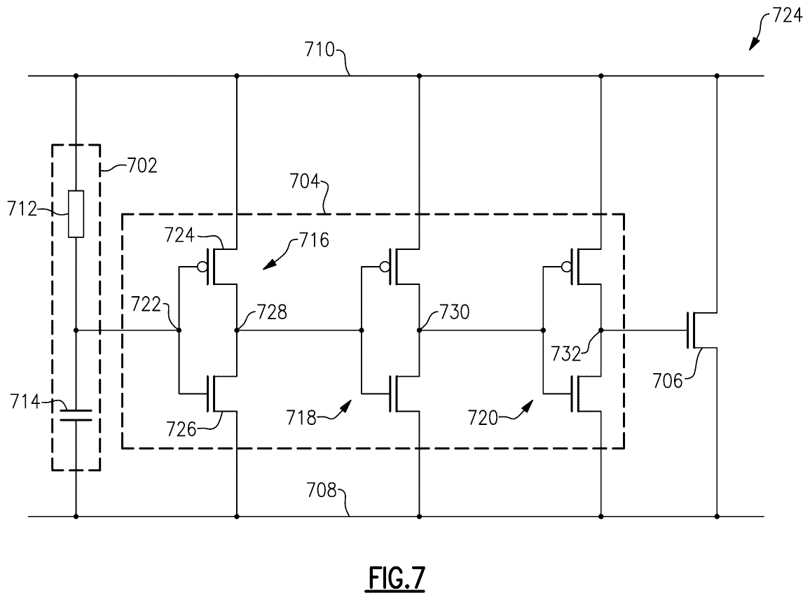

As illustrated in FIG. 5, a conductive trace 622 may be routed from the power supply pin 502 into the CMOS die 514 for discharging ESD charge on the power supply pin 502. More specifically, the ESD circuitry 624 that is fabricated based on a CMOS process can be connected to the power supply pin 502 through the conductive trace 622 to provide superior ESD protection as discussed above with respect to FIG. 4. The ESD circuitry 624 can include some or all of voltage spike detection circuitry, current spike protection circuitry, circuitry configured to pull a voltage down to a safe level, and circuitry configured to pull a current down to a safe level. Such circuitry can include one or more CMOS inverters. For example, the ESD circuitry 624 in some implementations can be the circuit 624 of FIG. 7. However, routing the conductive trace 622 around the GaAs die 512 to connect the power supply pin 502 and the ESD circuitry 624 may result in higher cost of packaging the GaAs die 512 and the CMOS die 514 into the packaged module 600. For example, to accommodate the conductive trace 622, the packaged module 600 may be fabricated using relatively expensive packaging technologies such as multi-chip modules (MCM) and molded interconnect substrate (MIS), instead of more economic packaging technologies such as quad flat no-lead (QFN) packaging.

Alternatively, a conductive trace 626 can be routed from the power supply pin 502 to the CMOS die 514 through the GaAs die 512. As such, the conductive trace 626 may connect the power supply pin 502 and the ESD circuitry 624 so that the ESD circuitry 624 can discharge ESD charge on the power supply pin 502. Compared with the conductive trace 622, less circuitous routing associated with the conductive trace 626 may allow for use of less expensive packaging technologies than with the circuitous conductive trace 622. Yet, the conductive trace 626 routed through and on the GaAs die 512 may cause coupling issues associated with front-end circuitry (e.g., the HBT 504) on the GaAs die 512. Additionally, routing the conductive trace 626 on the GaAs die 512 may increase the cost of manufacturing the GaAs die 512 because, for example, the need of an additional metal layer for routing the conductive trace 626.

### (2) ESD Protection Through RF Matching Network

To address at least some of the above problems, aspects of below disclosure disclose systems and techniques which can be used to provide ESD protection utilizing CMOS technologies without incurring extra cost of manufacturing associated with routing from a power supply pin or a power bus to a far-end CMOS die.

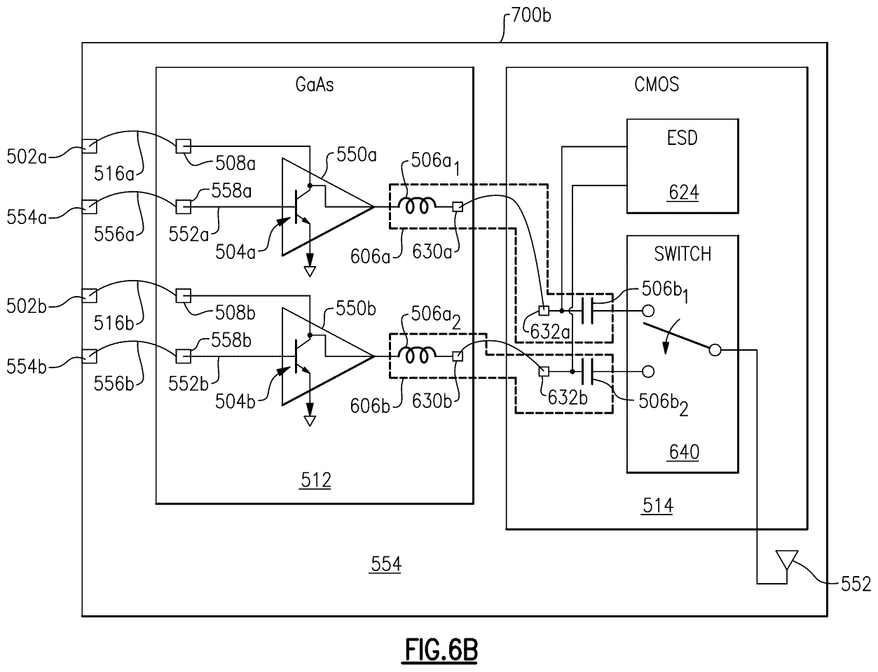

FIG. 6A is a schematic diagram of a packaged module 700 in accordance with some embodiments of the present disclosure. As shown in FIG. 6A, the packaged module 700 includes the GaAs die 512, the CMOS die 514, and the power supply pin 502. The GaAs die 512 includes the HBT 504, the terminal 508, and a matching network 606 that includes a terminal 630, a terminal 632, a bond wire 634, the inductor 506A and the capacitor 506B. The CMOS die 514 includes circuitry 640 that can perform various functionalities and the ESD circuitry 624. For example, the circuitry 640 can include, a radio frequency switch such as a band select switch or an antenna switch. The power supply pin 502 is connected to the terminal 508 through the bond wire 516. The terminal 508 is connected to the collector 520 of the HBT 504. The terminal 630 is connected to the terminal 632 on the CMOS die 514 through the inter-die bond wire 634.

As illustrated in FIG. 6A, the matching network 606 is split over the GaAs die 512 and the CMOS die 514. More specifically, the inductor 506A is deployed on the GaAs die 512 while the capacitor 506B is deployed on the CMOS die 514. As shown, a combined DC+RF Out signal 642 is presented on the collector 520 of the HBT 504 that includes both 1) a DC component which may carry ESD events caused by the supply 502 and 2) an amplified RF signal corresponding to an amplified version of an RF input signal presented on the base of the HBT 504. In the embodiment of FIG. 6A, a DC blocking path exists between the collector 520 of the HBT 504 and the circuitry 640 in the CMOS die 514, due to the presence of the DC blocking capacitor 506B. This can be because, while the inductor 506A allows DC to pass to the terminal 632 of the CMOS die 514, the capacitor 506B blocks DC from reaching the circuitry 640. Thus, an RF Out signal 646 including only the amplified RF signal without the DC component is passed to the load circuitry 640. Further, due to the placement of the DC blocking capacitor 506B on the CMOS die 514, a direct current (DC) path exists between the power supply pin 502 and the ESD circuitry 624, and the DC+RF Out signal 642 including the DC component and the amplified RF signal is thus passed to the ESD circuitry 624. In particular, the DC+RF Out signal 642 is passed from the supply pin 502 through the bond wire 516, the terminal 508, the inductor 506A, the terminal 630, the bond wire 634, and the terminal 632, again because DC passes through the inductor 506A, is blocked by the capacitor 506B, and instead passes to the ESD circuitry 624.

Thus, the ESD circuitry 624 fabricated on the CMOS die 514 may discharge ESD charge on the power supply pin 502 through the direct DC path provided by the matching network 606 to achieve more sophisticated ESD protection compared with the packaged module 500. Without resorting to conductive traces such as the conductive trace 622 or the conductive trace 626 for connecting the ESD circuitry 624 to the power supply pin 502, the cost of manufacturing the packaged module 700 may be more economic compared with the packaged module 600. For example, the ESD circuitry 624 can include some or all of voltage spike detection circuitry, current spike protection circuitry, circuitry configured to pull a voltage down to a safe level, and circuitry configured to pull a current down to a safe level. Such circuitry can include one or more CMOS inverters.

FIG. 6B shows another embodiment of a packaged module 700b. The packaged module 700b can be similar to the packaged module 700a of FIG. 6A except that the packaged module 700b of FIG. 6B includes two amplifying transistors 504a, 504b connected to two supply pins 502a, 502b instead of a single transistor connected to a single supply pin.

The amplifying transistors 504a, 504b each form part of a respective power amplifier 550a, 550b configured to amplify a radio frequency input signal 552a, 552b received via a path extending from a radio frequency input pin 554a, 554b, over a bond wire 556a, 556b, to a terminal 558a, 558b on the GaAs die 512, like in FIG. 6A.

Each transistor 504a, 504b is powered by a supply signal received from a path extending from a respective supply pin 502a, 502b to a collector of the transistor 504a, 504b. The output of each amplifier 550a, 550b, which in the illustrated embodiment corresponds to the collector of each transistor 504a, 504b, is connected to a respective terminal 632a, 632b on the CMOS die 514 via a impedance matching circuit 606a, 606b, like in FIG. 6A.

In FIG. 6B, the load circuitry comprises an antenna switch 640 that can be controlled to selectively connect to an antenna 552 either the amplified radio frequency output provided by the first power amplifier 550a or by the power amplifier 550b. The antenna 552 is on a substrate 554 of the module 700b in FIG. 6B, but can alternatively be provided on an external component, such as a phone board on which the module 700b is mounted.

As shown, similar to FIG. 6A, the ESD circuitry 624 is connected to each amplified signal path before the respective blocking capacitors 506b1, 506b2. Thus, the ESD circuitry 624 will receive DC signal content output by the simplifiers 550a, 550b including ESD events from the supply pins 502a, 502b. As such, the ESD circuitry 624 can act to discharge or otherwise protect against or reduce the impact of ESD events.

### Example ESD Protection Circuitry

FIG. 7 is a schematic diagram of one embodiment of the ESD circuitry 624 according to certain implementations. The ESD circuitry 624 includes timing circuit 702, inverter circuit 704, and clamping transistor 706 that is coupled between ground 708 and a power bus 710. The power bus 710 can be DC-coupled to the power supply pin 502 through the terminal 632, the bond wire 634, the terminal 630, the inductor 506A, the terminal 508, and the bond wire 516 as illustrated in FIG. 6A. As such, the power bus 710 in FIG. 7 may be biased at a steady power supply voltage of, for example, between 1.0 volt to 5.0 volts, depending on a voltage level applied on the power supply pin 502.

The timing circuit 702 includes resistor 712 and capacitor 714. The inverter circuit 704 includes inverter stages 716, 718, and 720, which are coupled in series between the timing circuit 702 and the clamping transistor 706. Inverter stage 716 includes a transistor 724 and a transistor 726. The transistor 724 can be a P-channel FET (PFET), coupled with the transistor 726 that can be a N-channel FET (NFET). Inverter stages 718 and 720 are substantially similar in transistor type and configuration as inverter stage 716.

As shown in FIG. 7, the resistor 712 is coupled between a node 722 and the power bus 710. The capacitor 714 is coupled between the node 722 the ground 708. Further, inverter stages 716, 718, and 720 are coupled in series between the node 722 and the gate of clamping transistor 706. Inverter stages 716, 718, and 720 are also coupled between the power bus 710 and the ground 708. The source of the clamping transistor 706 is coupled to the ground 708, and the drain of the clamping transistor 706 is coupled to the power bus 710. The clamping transistor 706 can include an array of FETs, such as NFETs, coupled together in parallel to enable the clamping transistor 706 to discharge a large amount of current from the power supply pin 502 during an ESD event.

### Example Mobile Device

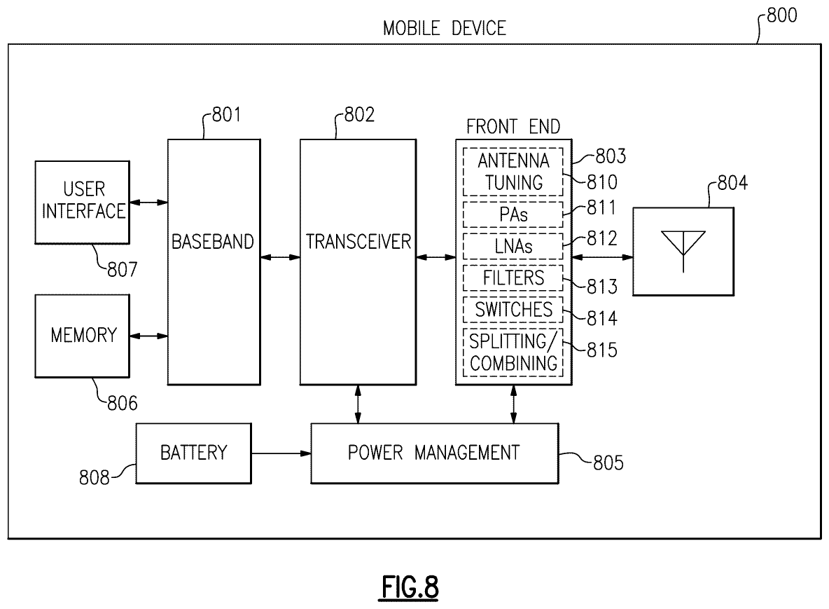

FIG. 8 is a schematic diagram of one embodiment of a mobile device 800. The mobile device 800 includes a baseband system 801, a transceiver 802, a front end system 803, antennas 804, a power management system 805, a memory 806, a user interface 807, and a battery 808.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 8 as the transceiver 802. In one example, separate components (for instance, separate circuits or dies) can be provided for handling certain types of RF signals.

The front end system 803 aids in conditioning signals transmitted to and/or received from the antennas 804. In the illustrated embodiment, the front end system 803 includes antenna tuning circuitry 810, power amplifiers (PAS) 811, low noise amplifiers (LNAs) 812, filters 813, switches 814, and signal splitting/combining circuitry 815. However, other implementations are possible.

For example, the front end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 8, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 8, the power management system 805 receives a battery voltage from the battery 808. The battery 808 can be any suitable battery for use in the mobile device 800, including, for example, a lithium-ion battery.

### Example Semiconductor Package Module

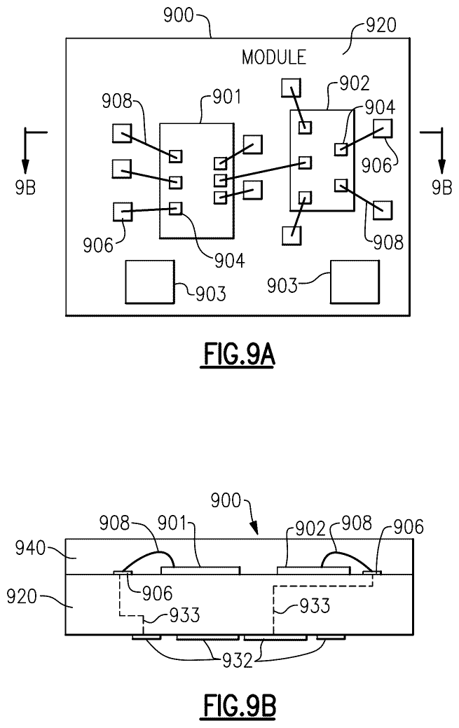

FIG. 9A is a schematic diagram of one embodiment of a packaged module 900. FIG. 9B is a schematic diagram of a cross-section of the packaged module 900 of FIG. 9A taken along the lines 9B-9B.

The packaged module 900 illustrates an example of a module that can include circuitry implemented in accordance with one or more features of the present disclosure.

The packaged module 900 includes a first die 901, a second die 902, surface mount components 903, wirebonds 908, a package substrate 920, and encapsulation structure 940. The package substrate 920 includes pads 906 formed from conductors disposed therein. Additionally, the dies 901, 902 include pads 904, and the wirebonds 908 have been used to connect the pads 904 of the dies 901, 902 to the pads 906 of the package substrate 920.

In certain implementations, the dies 901, 902 are manufactured using different processing technologies. In one example, the first die 901 is manufactured using a compound semiconductor process, and the second die 902 is manufactured using a silicon process. Although an example with two dies is shown, a packaged module can include more or fewer dies. More specifically, the first die 901 may be the GaAs die 512 and the second die 902 may be the CMOS die 514.

The package substrate 920 can be configured to receive a plurality of components such as the dies 901, 902 and the surface mount components 903, which can include, for example, surface mount capacitors and/or inductors.

As shown in FIG. 9B, the packaged module 900 is shown to include a plurality of contact pads 932 disposed on the side of the packaged module 900 opposite the side used to mount the dies 901, 902. Configuring the packaged module 900 in this manner can aid in connecting the packaged module 900 to a circuit board such as a phone board of a wireless device. The example contact pads 932 can be configured to provide RF signals, bias signals, ground, and/or supply voltages to the dies 901, 902 and/or the surface mount components 903. As shown in FIG. 9B, the electrically connections between the contact pads 932 and the dies 901, 902 can be facilitated by connections 933 through the package substrate 920. The connections 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling of the packaged module 900. Such a packaging structure can include overmold or encapsulation structure 940 formed over the package substrate 920 and the surface mount component(s) and die(s) disposed thereon.

It will be understood that although the packaged module 900 is described in the context of electrical connections based on wirebonds, one or more features of the present disclosure can also be implemented in other packaging configurations, including, for example, flip-chip configurations.

### CONCLUSION

It should be noted that a number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A semiconductor module comprising:
a power supply pin;
a module substrate;
a compound semiconductor die supported by the module substrate, the compound semiconductor die including a first amplifying transistor and a first matching component of an impedance matching network, the first matching component coupled to an output of the first amplifying transistor and configured to pass low frequency; and
a silicon-based die supported by the module substrate, the silicon-based die including electrostatic discharge circuitry coupled, via an inter-die connection between the compound semiconductor die and the silicon-based die, to an output of the first matching component, the silicon-based die further including a radio frequency switching device and a second matching component of the impedance matching network configured to block low frequency, the second matching component coupled between the output of the first matching component and the radio frequency switching device.

2. The semiconductor module of claim 1 wherein the compound semiconductor die is a III-V semiconductor die.

3. The semiconductor module of claim 2 wherein the silicon-based die is a complementary metal-oxide-semiconductor die or a silicon-on-insulator die.

4. The semiconductor module of claim 1 wherein the first amplifying transistor is a heterojunction bipolar transistor or a Pseudomorphic High-Electron-Mobility-Transistor.

5. The semiconductor module of claim 1 wherein the first matching component is an inductor.

6. The semiconductor module of claim 5 wherein the second matching component is a capacitor.

7. The semiconductor module of claim 1 wherein the impedance matching network matches the output of the first amplifying transistor to an input of the radio frequency switching device.

8. The semiconductor module of claim 1 wherein the compound semiconductor die is supported by the module substrate in a position such that the compound semiconductor die is between the power supply pin and the silicon-based die.

9. A semiconductor module including:
a power supply pin;
a module substrate;
a first die supported by the module substrate, the first die including a first transistor and a first matching component of a radio frequency matching network; and
a second die supported by the module substrate, the second die including electrostatic discharge circuitry and a second matching component of the radio frequency matching network, the radio frequency matching network configured to match an impedance associated with the first transistor, the first matching component providing a conductive path between the electrostatic discharge circuitry and the power supply pin.

10. The semiconductor module of claim 9 wherein the first die is a compound semiconductor die and the second die is a silicon-based die.

11. The semiconductor module of claim 10 wherein the first die is a III-V semiconductor die and the second die is a complementary metal-oxide-semiconductor die or a silicon-on-insulator die.

12. A semiconductor module comprising:
a power supply pin;
a module substrate;
a first die supported by the module substrate and coupled to the power supply pin, the first die including a first passive component; and
a second die supported by the module substrate, the second die including electrostatic discharge circuitry, a radio frequency device, a second passive component, the first passive component forming part of a direct current (DC) path between the power supply pin and the electrostatic discharge circuitry, the second passive component in a path between the power supply pin and the radio frequency device and configured to block direct current (DC) from reaching the radio frequency device.

13. The semiconductor module of claim 12 wherein the first die is a compound semiconductor die.

14. The semiconductor module of claim 13 wherein the first die is a III-V semiconductor die.

15. The semiconductor module of claim 13 wherein the second die is a silicon-based die.

16. The semiconductor module of claim 15 wherein the second die is a complementary metal-oxide-semiconductor die or a silicon-on-insulator die.

17. The semiconductor module of claim 12 wherein the first die further includes a heterojunction bipolar transistor or a Pseudomorphic High-Electron-Mobility-Transistor powered by a supply signal provided by the power supply pin.

18. The semiconductor module of claim 12 wherein the first passive component is an inductor.

19. The semiconductor module of claim 18 wherein the second passive component is a capacitor.

20. A mobile device comprising a transceiver, an antenna, and the semiconductor module of claim 12 arranged between the transceiver and the antenna.
